(19) United States
(12) Patent Application Publication
(10) Pub. No.: US 2003/0221848 A1
(43) Pub. Date: Dec. 4, 2003

(54) Antimagnetic shielding case structure

(75) Inventor: Hung-Chun Wu, Taoyuan (TW)

Correspondence Address: BRUCE H. TROXELL, SUITE 1404, 5205 LEESBURG PIKE, FALLS CHURCH, VA, 22041, US

(73) Assignee: Speed Tech Corp.

(21) Appl. No.: 10/154,804

(22) Filed: May 28, 2002

(51) Int. Cl. H05K 9/00

(52) U.S. Cl. 174/35 R

(57) ABSTRACT

Antimagnetic shielding case structure made of a very thin metal sheet or film. When manufactured, the antimagnetic shielding case is placed in a predetermined position in the mold for molding the insulating case of a product. When a material is injected into the mold and molded, the antimagnetic shielding case is simultaneously formed in a predetermined position on outer face of inner face of the insulating case and integrally connected with the insulating case without protruding from the surface thereof. The metal sheet or film serves to provide an antimagnetic and isolative effect.

### BACKGROUND OF THE INVENTION

The present invention is related to an antimagnetic shielding case structure which is easy to manufacture at low cost and high production efficiency.

It is known that leakage of electromagnetic wave leads to great affection on all kinds of electronic circuits, especially sophisticated electronic circuits. The leaking electromagnetic wave will induce current to interfere with the operation of electronic elements and electronic circuits or even make the circuit mis-operate or fail. Therefore, it is important to reduce or avoid leakage of electromagnetic wave for the developers of all kinds of circuits.

FIG. 1 shows a conventional antimagnetic shielding case widely used in mobile phone, PDA, etc. A metal sheet is directly bent into a frame 5 in accordance with the portion of the circuit board to be isolated. The periphery of the frame 5 has perpendicularly downward extending skirts 51 to be soldered on the circuit board for grounding. The center of the top of the frame 5 is formed with a hollow section 52. An upper cover board 6 covers the frame 5. The periphery of the upper cover board 6 has skirts 61 formed with protuberances or other engaging structures for engaging with the frame 5. The upper cover board 6 is detachable from the frame 5 for easy manufacturing, maintenance and adjustment. In order to minimize the possibility of penetration of the electromagnetic wave, the shielding case is avoided to have any gap or perforation as possible. However, it is a trend to manufacture products with small volume and light weight so that the metal sheet material of the frame 5 and the upper cover board 6 is light and thin and has insufficient strength. Therefore, the antimagnetic shielding case made of such metal sheet is easy to deform and gaps may be formed between the connecting sections of the frame 5 and upper cover board 6. As a result, the antimagnetic effect will be affected and the electromagnetic wave may leak. Accordingly, it is strictly required that the metal sheet material has true planarity. Also, it is highly required that the metal sheet material is packed and transferred without being damaged or deformed. This leads to very high manufacturing cost. Also, the cost for transfer and management of the material is increased.

Furthermore, the frame 5 and upper cover board 6 are disposed between the circuit board and the insulating housing. In order to avoid short circuit or obstruction to the assembly, generally, a peripheral space is reversed around the metal shielding case. This leads to increased height.

### SUMMARY OF THE INVENTION

It is therefore a primary object of the present invention to provide an antimagnetic shielding case structure made of a very thin metal sheet or film. When manufactured, the antimagnetic shielding case is placed in a predetermined position in the mold for molding the insulating case of a product. When a material is injected into the mold and molded, the antimagnetic shielding case is simultaneously formed in a predetermined position on outer face of inner face of the insulating case and integrally connected with the insulating case without protruding from the surface thereof. The metal sheet or film serves to provide an antimagnetic and isolative effect. Accordingly, the manufacturing procedure is simplified and the manufacturing cost is lowered.

It is a further object of the present invention to provide the above antimagnetic shielding case structure which is manufactured without using any other processing tool. When molding the insulating case, the antimagnetic shielding case is simultaneously embedded in the insulating case. Therefore, it is unnecessary to further process the antimagnetic shielding case so that the production efficiency is increased.

It is still a further object of the present invention to provide the above antimagnetic shielding case structure which is integrally connected with the insulating case so that the antimagnetic shielding case is unnecessary to have sufficient strength for keeping a fixed shape and the precision in dimension of the antimagnetic shielding case is not strictly required. Accordingly, the antimagnetic shielding case can be made of very thin film to greatly reduce the cost for the material.

The present invention can be best understood through the following description and accompanying drawings wherein:

### BRIEF DESCRIPTION OF THE DRAWINGS

FIG. 1 is a perspective view of a conventional antimagnetic shielding case;

FIG. 2 is a sectional view showing the forming procedure of a first embodiment of the present invention in one state;

FIG. 3 is a sectional view showing the forming procedure of the first embodiment of the present invention in another state;

FIG. 4 is a sectional view showing the structure of the first embodiment of the present invention;

FIG. 5 is a sectional view showing the forming procedure of a second embodiment of the present invention in one state;

FIG. 6 is a sectional view showing the forming procedure of the second embodiment of the present invention in another state; and

FIG. 7 is a sectional view showing the structure of the second embodiment of the present invention

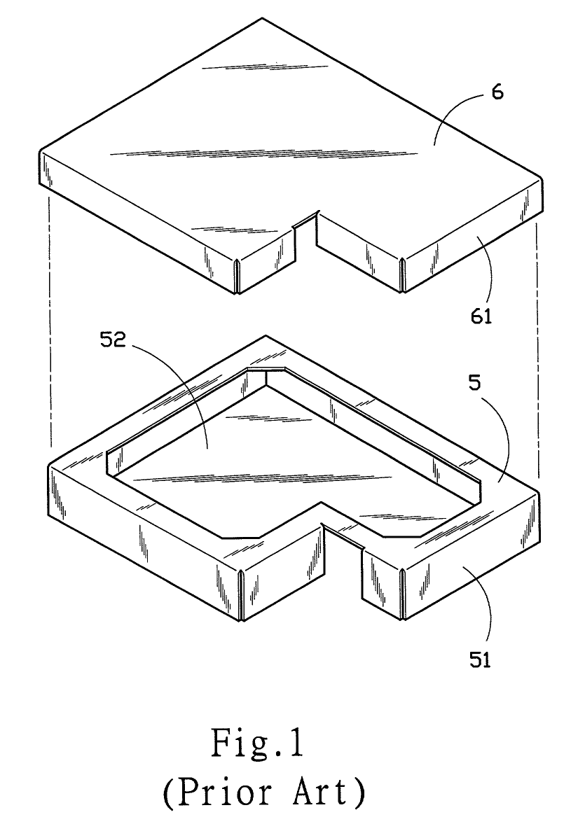

### DETAILED DESCRIPTION OF THE PREFERRED EMBODIMENTS

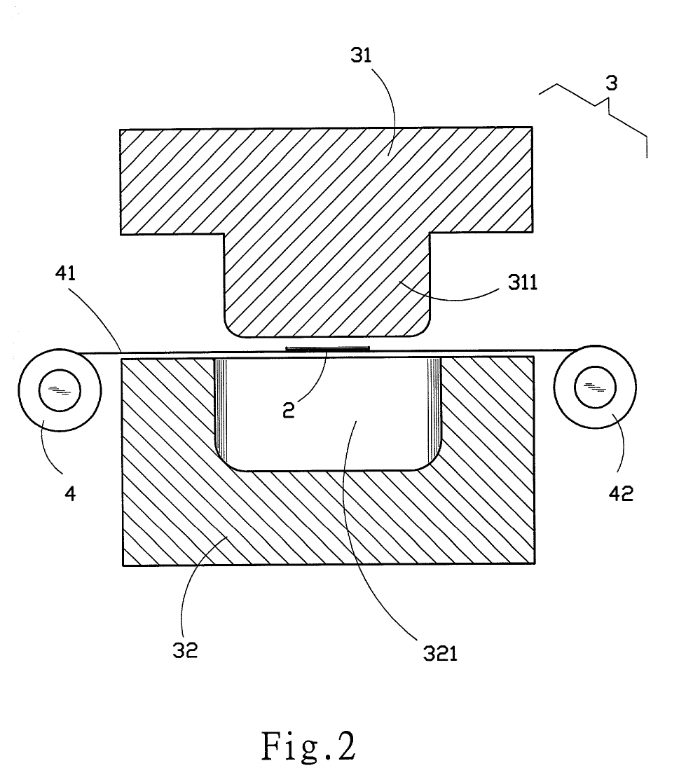

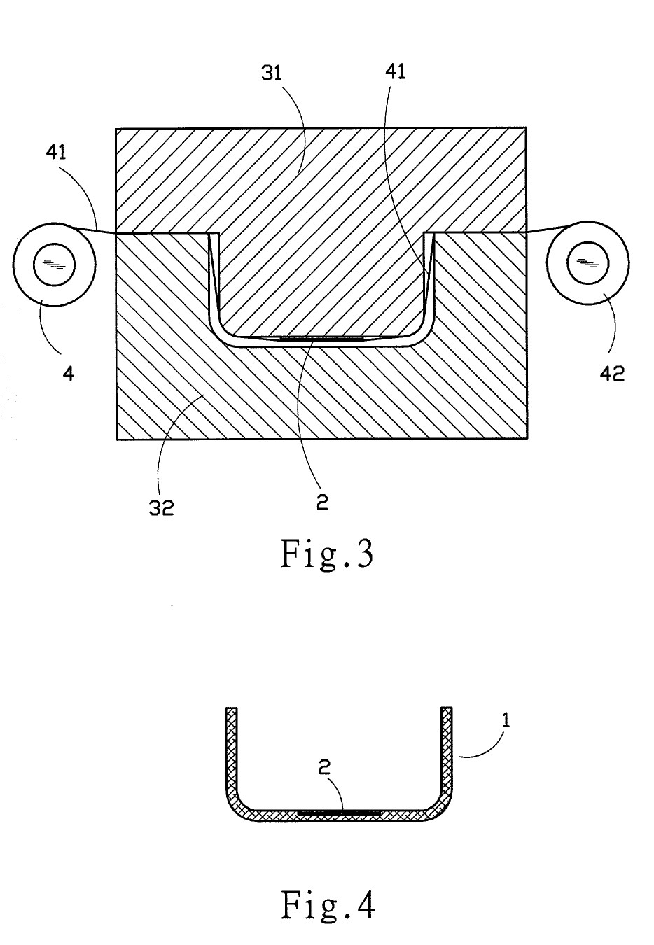

Please refer to FIGS. 2 to 4. The antimagnetic shielding case 2 of the present invention is made of a very thin metal film disposed on a soft material belt 41. The material belt 41 can be wound into a material roll 4. When manufacturing the antimagnetic shielding case, a winding reel 42 drives the material belt 41 to pass through the space between a male mold 31 and a female mold 32 of an injection molding device 3. The female mold 32 is formed with a cavity 321 and the male mold 31 has a corresponding projecting section. When the male mold 31 is mated with the female mold 32, the projecting section 311 of the male mold 31 presses the antimagnetic shielding case 2 on the material belt 41 into the cavity 321. A molding space is defined between the projecting section 311 and the wall of the cavity 321. When the plastic material is injected into the molding space, the material belt 41 is molten in the plastic material. After cooled and demolded, an insulating case 1 is formed and the antimagnetic shielding case 2 is integrally formed in a predetermined position on inner side of the insulating case 1.

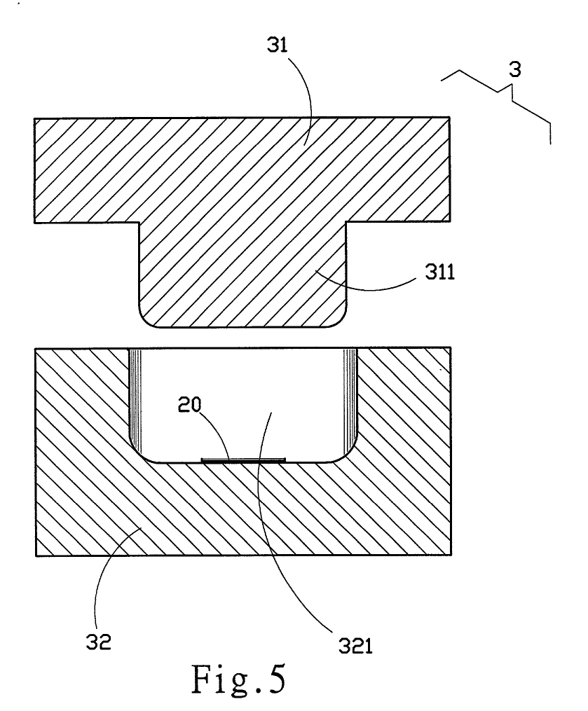

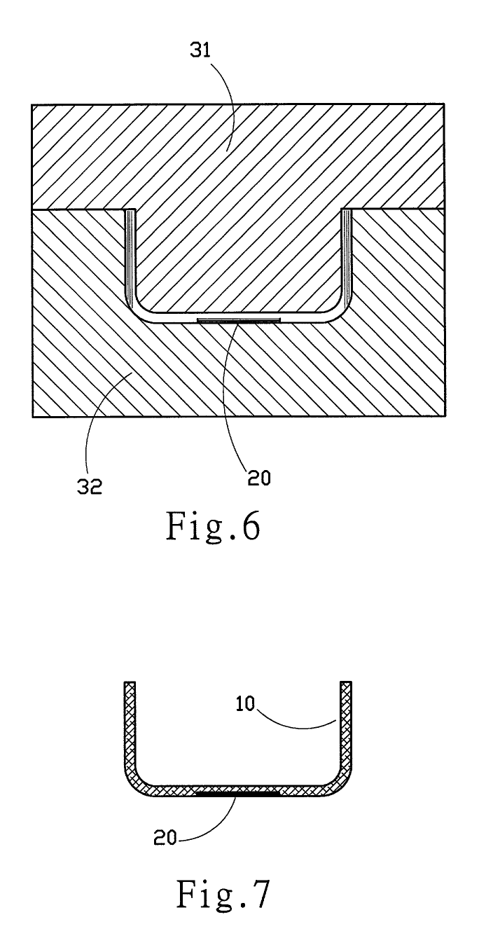

FIGS. 5 to 7 show a second embodiment of the present invention, in which the antimagnetic shielding case 20 is also made as a film. When manufactured, the antimagnetic shielding case 20 is directly placed in a predetermined position in the cavity 321 of the female mold 32. Then the male mold 31 is mated with the female mold 32 and the plastic material is injected. After cooled and demolded, an insulating case 10 is formed and the antimagnetic shielding case 20 is integrally formed in a predetermined position on outer side of the bottom of the insulating case 10.

In the above structures, the antimagnetic shielding cases 2 and 20 have poor strength and are easy to deform when suffering external force. Therefore, the precision in dimension and shape of the antimagnetic shielding cases 2 and 20 is not strictly required when manufactured. Instead, by means of the injection pressure of the plastic material, the antimagnetic shielding cases 2 and 20 are tightly attached to the mold 3 and naturally formed into a predetermined shape. Accordingly, the costs for both the material and processing are lowered.

According to the above structures, the conventional metal antimagnetic shielding case between the insulating case and the circuit board is omitted. Therefore, the space for soldering the antimagnetic shielding case on the circuit board is saved so that the layout of the circuit board becomes more elastic and the area of the circuit board can be reduced. Also, without the limitation of the antimagnetic shielding case, the distance between the insulating case and the circuit board is shortened so as to reduce the volume of the product.

According to the above structures, by means of conventional processing measure, the antimagnetic shielding case 2 is embedded in the insulating case 1 without protruding therefrom. The present invention is widely applicable to other products or elements having insulating cases and demanding antimagnetic effect. For example, the present invention can serve as an antimagnetic member of the housings of various connectors to achieve antimagnetic and isolative effect.

The above embodiments are only used to illustrate the present invention, not intended to limit the scope thereof. Many modifications of the above embodiments can be made without departing from the spirit of the present invention.

What is claimed is:

1. Antimagnetic shielding case structure comprising an insulating case and an antimagnetic shielding case, the insulating case being formed with a predetermined shape in accordance with a product, said antimagnetic shielding case structure being characterized in that when molding the insulating case, the antimagnetic shielding case is simultaneously formed in a predetermined position on the insulating case and integrally connected therewith without protruding from a surface of the insulating case.

2. Antimagnetic shielding case structure as claimed in claim 1, wherein the antimagnetic shielding case is embedded in an side of the insulating case.

3. Antimagnetic shielding case structure as claimed in claim 1, wherein the antimagnetic shielding case is embedded in an inner side of the insulating case.
